(19) United States
(12) Patent Application Publication
(10) Pub. No.: US 2009/0102532 A1
(43) Pub. Date: Apr. 23, 2009

(54) Latch circuit

(75) Inventors: Masatomo Eimitsu, Kanagawa (JP); Takanori Saeki, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC Electronics Corporation, Kawasaki (JP)

(21) Appl. No.: 12/232,071

(22) Filed: Sep. 10, 2008

(30) Foreign Application Priority Data
Oct. 23, 2007 (JP) 274563/2007

(51) Int. Cl. H03K 3/356; H03K 3/00

(52) U.S. Cl. 327/208; 327/218

(57) ABSTRACT

A latch circuit includes: a first terminal; a second terminal; a first data-gating circuit coupled to the first terminal and the second terminal, the first data-gating circuit non-reversely gating the second signal in response to the first signal to reveal a third signal; a second data-gating circuit coupled to the first terminal and the second terminal, the second data-gating circuit reversely gating the second signal in response to the first signal to reveal a fourth signal; a third terminal receiving a fifth signal; a selector circuit coupled to the first data-gating circuit and the second data-gating circuit, the selector circuit outputting one of the third signal and the fourth signal in response to the fifth signal to latch one of the third signal and the fourth signal, respectively; and a bistable circuit coupled to the selector circuit, the bistable circuit holding one of the third signal and the fourth signal.

### BACKGROUND OF THE INVENTION

1. Field of the Invention

The present invention relates to a latch circuit and a semiconductor device.

2. Description of the Related Art

FIG. 6 is a diagram for embodying a flip-flop 1 described in JP 11-145788 A. In the flip-flop 1, reference numeral 10 denotes a general-purpose D flip-flop. The D flip-flop 10 has a structure in which a single-phase clock is input thereinto via a selector circuit 7.

The selector circuit 7 selectively switches a state under which a clock input to a clock input terminal 3 is non-reversely output, and another state under which a clock input to the clock input terminal 3 is reversely output in response to a selection signal which is input to a selection terminal 4.

As described above, the operation modes of the flip-flop 1 can be easily switched, namely, one operation mode for operating the flip-flop 1 at a rising edge of an input clock, and another operation mode for operating the flip-flop 1 at a falling edge of the input clock are easily switched. As a result, the flip-flop 1 can perform timing control operation based on a change in polarities of clock edges. Other relevant latch circuits have been described in, for instance, JP 06-260901 A and JP 10-083693 A.

However, the above-mentioned conventional technologies have a problem in that the timing of the D flip-flop 10 is restricted. More specifically, restrictions of data holding time are suppressed.

A clock input to the clock input terminal 3 is required to constitute logic (namely, selector circuit 7) between the own clock and a selecting signal input to a selection terminal 4. As a consequence, timing at which the input clock reaches the D flip-flop 10 is delayed by such a delay time equivalent to the selector circuit 7. As a result, the D flip-flop 10 must secure the data holding time defined by the delay time as extra time.

### SUMMARY

In order to solve the above-mentioned problems, a latch circuit according to a first aspect of the present invention includes: a first terminal receiving a first signal; a second terminal receiving a second signal; a first data-gating circuit coupled to the first terminal and the second terminal, the first data-gating circuit non-reversely gating the second signal in response to the first signal to reveal a third signal; a second data-gating circuit coupled to the first terminal and the second terminal, the second data-gating circuit reversely gating the second signal in response to the first signal to reveal a fourth signal; a third terminal receiving a fifth signal; a selector circuit coupled to the first data-gating circuit and the second data-gating circuit, the selector circuit outputting one of the third signal and the fourth signal in response to the fifth signal to latch one of the third signal and the fourth signal, respectively; and a bistable circuit coupled to the selector circuit, the bistable circuit holding one of the third signal and the fourth signal.

A latch circuit according to a second aspect of the present invention includes: a first data-gating circuit non-reversely switching in response to a first signal; a second data-gating circuit non-reversely switching in response to a second signal; a first circuit including the first data-gating circuit and the second data-gating circuit coupled together in series; a third data-gating circuit reversely switching in response to the first signal; a fourth data-gating circuit reversely switching in response to the second signal; a second circuit including the third data-gating circuit and the fourth data-gating circuit coupled together in series; a first terminal receiving a third signal; a second terminal revealing a fourth signal; a third circuit including one circuit, the one circuit including the first circuit and the second circuit coupled together in parallel, the one circuit having one terminal being coupled to the first terminal and another terminal being coupled to the second terminal; and a bistable circuit coupled to the second terminal, the bistable circuit holding the fourth signal.

A latch circuit according to a third aspect of the present invention includes: a first transistor being of a first conduction type and switching in response to a first signal; a second transistor being of the first conduction type and switching in response to a second signal; a first circuit including the first transistor and the second transistor coupled together in series; a third transistor being of a second conduction type different from the first conduction type and switching in response to the first signal; a fourth transistor being of the second conduction type and switching in response to the second signal; a second circuit including the third transistor and the fourth transistor coupled together in series; a first terminal receiving a third signal; a second terminal revealing a fourth signal; a third circuit including one circuit, the one circuit including the first circuit and the second circuit coupled together in parallel, the one circuit having one terminal being coupled to the first terminal and another terminal being coupled to the second terminal; and a bistable circuit coupled to the second terminal, the bistable circuit holding the fourth signal.

According to the present invention, it is possible to provide the latch circuit capable of performing the timing control based on changes in polarities of clock edges without suppressing the restrictions of the data holding time.

### BRIEF DESCRIPTION OF THE DRAWINGS

In the accompanying drawings:

FIG. 1 is a block diagram showing a latch circuit according to a first embodiment of the present invention;

FIG. 2 is a circuit diagram showing a latch circuit according to a second embodiment of the present invention;

FIG. 3 is a circuit diagram showing a latch circuit according to a third embodiment of the present invention;

FIG. 4 is a circuit diagram showing a latch circuit according to a fourth embodiment of the present invention;

FIG. 5 is a circuit diagram showing a latch circuit according to a fifth embodiment of the present invention; and

FIG. 6 is a block diagram showing a conventional flip-flop.

### DETAILED DESCRIPTION OF THE PREFERRED EMBODIMENTS

Referring now to drawings, a detailed description is made of latch circuits and semiconductor devices as various concrete embodiments to which the present invention has been applied. It should be understood that the same structural elements are denoted by the same reference numerals in the respective drawings, and overlapped descriptions thereof are omitted in order to avoid cumbersome descriptions, if necessary.

### First Embodiment

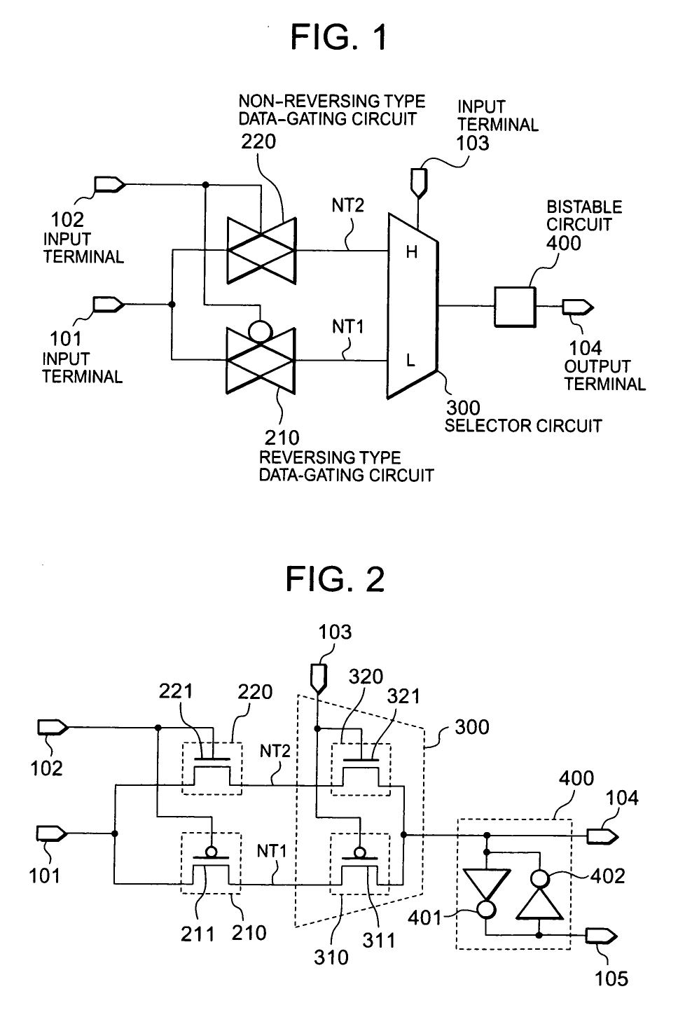

FIG. 1 is a block diagram showing a structure of a latch circuit according to a first embodiment of the present invention. In this drawing, reference numeral 101 denotes an input terminal for receiving data; reference numeral 102 denotes an input terminal for receiving a clock or a selecting signal; reference numeral 103 denotes a terminal for receiving a selecting signal or a clock; and reference numeral 104 denotes an output terminal for revealing data.

Reference numerals 210 and 220 denote a reversing type data-gating circuit and a non-reversing type data-gating circuit, respectively. More specifically, those data-gating circuits 210 and 220 include, for example, a bilateral gate circuit and a pass-transistor circuit which have bidirectional characteristics, or a clocked inverter circuit which has unidirectional characteristics.

Reference numeral 300 denotes a selector circuit. In response to a signal input to the input terminal 103 of the selector circuit 300, the selector circuit 300 reveals a signal which appears at a terminal NT1 or a terminal NT2 of the selector circuit 300. In the case of the first embodiment, when a level of a signal input to the input terminal 103 is “Low” (hereinafter, abbreviated as “L”), the selector circuit 300 reveals a signal appearing at the terminal NT1. Also, when a level of a signal input to the input terminal 103 is “High” (hereinafter, abbreviated as “H”), the selector circuit 300 reveals a signal appearing at the terminal NT2.

Reference numeral 400 denotes a bistable circuit which holds an output signal of the selector circuit 300, and outputs a signal to the output terminal 104 of the bistable circuit 400.

TABLE 1

| | input | input | | | input | | |
|---|---|---|---|---|---|---|---|
| transition | terminal | terminal | terminal | terminal | terminal | output | |
| state | 101 | 102 | NT1 | NT2 | 103 | terminal 104 | |
| (A) | H | L | H | Z | L | H | through |
| | L | | L | | | L | state |
| (B) | H | H | Z | H | | latched state | |
| | L | | | L | | | |
| (C) | H | L | H | Z | H | latched state | |
| | L | | L | | | | |
| (D) | H | H | Z | H | | H | through |
| | L | | | L | | L | state |

Table 1 is a truth table of the latch circuit shown in FIG. 1. The transition state (A) and the transition state (B) indicate states under which “L” is input to the input terminal 103. Moreover, the former transition state (A) shows such a state that “L” has been input to the input terminal 102, whereas the latter transition state (B) represents such a state that “H” has been input to the input terminal 102.

In the former transition state (A), under such a state that the gate of the reversing type data-gating circuit 210 is opened, the reversing type data-gating circuit 210 passes therethrough a signal input to the input terminal 101 to the terminal NT1. On the other hand, under such a state that the gate of the non-reversing type data-gating circuit 220 is closed, the non-reversing type data-gating circuit 220 represents a high impedance (hereinafter, abbreviated as “Z”) with respect to the terminal NT2 irrespective of a signal input to the input terminal 101.

Next, in the transition state (A), the selector circuit 300 reveals a signal appearing at the terminal NT1 irrespective of a signal appearing at the terminal NT2, or a state of this signal. The bistable circuit 400 holds the above-mentioned output signal, and also, outputs this output signal to the output terminal 104. This state is referred to as a through state of the latch circuit.

In the latter transition state (B), under such a state that the gate of the reversing type data-gating circuit 210 is closed, the reversing type data-gating circuit 210 represents “Z” with respect to the terminal NT1 irrespective of a signal input to the input terminal 101. On the other hand, under such a state that the gate of the non-reversing type data-gating circuit 220 is opened, the non-reversing type data-gating circuit 220 passes therethrough the signal input to the input terminal 101 to the terminal NT2.

It should be noted that the data gating operations performed by the data-gating circuits 210 and 220 have a reverse relation with respect to each other. In addition, if an operating relation between the data-gating circuits 210 and 220 has at least a reversing operation relation, the operating relation thereof satisfies a necessary and sufficient state. As a consequence, alternatively, reference numeral 210 may constitute a non-reversing type data-gating circuit, and reference numeral 220 may constitute a reversing type data-gating circuit.

Next, in the transition state (B), similarly to the transition state (A), the selector circuit 300 reveals a signal appearing at the terminal NT1 irrespective of a signal appearing at the terminal NT2, or a state of this signal. In this case, since the terminal NT1 is under the state of “Z”, the bistable circuit 400 maintains such a held value just before the bistable circuit 400 is brought into the transition state (B), and also, continuously outputs the held value to the output terminal 104. This state is referred to as a latched state of the latch circuit.

As described above, the transition states (A) and (B) represent a truth table of a reversing type latch circuit in which the input terminal 101 is an input terminal of data, the input terminal 102 is an input terminal of “reversed clock”, and the output terminal 104 is an output terminal of data.

The transition state (C) and the transition state (D) represent such states that “H” has been input to the input terminal 103. Further, specifically, the former transition state (C) shows such a state that “L” has been input to the input terminal 102, and the latter transition state (D) indicates such a state that “H” has been input to the input terminal 102.

In the former transition state (C), under such a state that the gate of the reversing type data-gating circuit 210 is opened, the reversing type data-gating circuit 210 passes therethrough a signal input to the input terminal 101 to the terminal NT1. On the other hand, under such a state that the gate of the non-reversing type data-gating circuit 220 is closed, the non-reversing type data-gating circuit 220 represents “Z” with respect to the terminal NT2 irrespective of a signal input to the input terminal 101.

Next, in the transition state (C), the selector circuit 300 reveals a signal appearing at the terminal NT2 irrespective of a signal appearing at the terminal NT1, or a state of this signal. In this case, since the terminal NT2 is under the state of “Z”, the bistable circuit 400 maintains such a held value just before the bistable circuit 400 is brought into the transition state (C), and also, continuously outputs the held value to the output terminal 104, which represents the latched state.

In the latter transition state (D), under such a state that the gate of the reversing type data-gating circuit 210 is closed, the reversing type data-gating circuit 210 represents “Z” with respect to the terminal NT1 irrespective of a signal input to the input terminal 101. On the other hand, under such a state that the gate of the non-reversing type data-gating circuit 220 is opened, the non-reversing type data-gating circuit 220 passes therethrough the signal input to the input terminal 101 to the terminal NT2.

Next, in the transition state (D), similarly to the transition state (C), the selector circuit 300 reveals a signal appearing at the terminal NT2 irrespective of a signal appearing at the terminal NT1, or a state of this signal, and also, the bistable circuit 400 holds the above-mentioned output signal and further outputs the output signal to the output terminal 104, which represents through state.

As described above, the transition states (C) and (D) represent a truth table of a non-reversing type latch circuit in which the input terminal 101 is an input terminal of data, the input terminal 102 is an input terminal of “non-reversed clock”, and the output terminal 104 is an output terminal of data.

As described above, the latch circuit shown in FIG. 1 is provided with an operation which allows the latch circuit to be readily changed into a latch circuit having the different polarities (namely, both reversing type latch circuit and non-inviting type latch circuit) in response to the signals input to the input terminal 103.

In addition, a description is made of effects of the latch circuit shown in FIG. 1. The clock input to the input terminal 102 is not required to constitute logic between the own clock and the signal input to the input terminal 103 (namely, signal for causing latch circuit to select polarity between reversing type and non-reversing type latch circuits). As a consequence, since there is no delay in timing when the above-mentioned clock reaches the data-gating circuit 210 or the data-gating circuit 220 (corresponding to original function elements as function of latch circuit), this clock never suppresses the restriction of the data holding time of latch circuit. In other words, the extra data holding time is no longer required to be secured.

TABLE 2

| | input | input | | | input | | |
|---|---|---|---|---|---|---|---|
| transition | terminal | terminal | terminal | terminal | terminal | output | |
| state | 101 | 102 | NT1 | NT2 | 103 | terminal 104 | |
| (A) | H | L | H | Z | L | H | through |
| | L | | L | | | L | state |
| (C) | H | | H | | H | latched state | |
| | L | | L | | | | |
| (B) | H | H | Z | H | L | latched state | |
| | L | | | L | | | |
| (D) | H | | | H | H | H | through |
| | L | | | L | | L | state |

Table 2 is also a truth table of the latch circuit shown in FIG. 1, and corresponds to a truth table equivalent to Table 1. It should be understood that Table 2 is such a table that the transition states (A) to (D) shown in Table 1 are re-arranged, namely, the transition states are re-arranged in the order from (A), (C), (B), to (D).

First, if an attention is paid to the transition states (A) and (C), those transition states represent a truth table of such a reversing type latch circuit that the input terminal 101 is an input terminal of data, the input terminal 103 is an input terminal of “reversed clock”, and the output terminal 104 is an output terminal of data.

Next, if an attention is paid to the transition states (B) and (D), those transition states represent a truth table of such a non-reversing type latch circuit that the input terminal 101 is an input terminal of data, the input terminal 103 is an input terminal of “non-reversed clock”, and the output terminal 104 is an output terminal of data.

As described above, the latch circuit shown in FIG. 1 can be easily changed into a latch circuit having the different polarities (namely, reversing type and non-reversing type latch circuits) in response also to the signal input to the input terminal 102.

### Second Embodiment

FIG. 2 is a circuit diagram showing a structure of a latch circuit according to a second embodiment of the present invention. It should be understood that the same structural elements as those shown in FIG. 1 are denoted by the same reference numerals in this second embodiment.

Firstly, a description is made of the structure of the latch circuit of FIG. 2 in view of one aspect. That is, a description is made of a structure of a selector circuit 300 shown in FIG. 2, which has the same elements as those of the selector circuit 300 shown in FIG. 1.

Reference numerals 310 and 320 denote a reversing type data-gating circuit and a non-reversing type data-gating circuit, respectively. If those data-gating circuits 310 and 320 are expressed by concrete circuit names, those data-gating circuits include, for instance, a bilateral gate circuit and a pass-transistor circuit which have bidirectional characteristics, or a clocked inverter circuit which has unidirectional characteristics.

The reversing type data-gating circuit 310 opens and closes a gate thereof in response to a signal input to the input terminal 103 so as to output a signal appearing at the terminal NT1 or a state of this signal to the output terminal 104. Similarly, the non-reversing type data-gating circuit 320 opens and closes a gate thereof in response to a signal input to the input terminal 103 so as to output a signal appearing at the terminal NT2 or a state of this signal to the output terminal 104.

In this case, the data-gating circuits 310 and 320 establish a reversing relation under data gating operations. In other words, in response to the signal input to the input terminal 103, when the reversing type data-gating circuit 310 is opened, the non-reversing type data-gating circuit 320 is closed, and conversely, when the reversing type data-gating circuit 310 is closed, the non-reversing type data-gating circuit 320 is opened. In addition, if the data-gating circuits 310 and 320 may satisfy at least a reversing operation relation therebetween, then those gating operations thereof are sufficiently required. As a consequence, alternatively, reference numeral 310 may denote a non-reversing type data-gating circuit, and reference numeral 320 may constitute a reversing type data-gating circuit.

When the relation is made based on this aspect, if the data-gating circuits 210 and 310 can establish a series coupling relation between the input terminal 101 and the output terminal 104, then the data-gating circuits 210 and 310 may be sufficiently operated. As a consequence, positional relation between the data-gating circuit 210 and the data-gating circuit 310 may be replaced with each other. Similarly, if the data-gating circuits 220 and 320 can also establish a series coupling relation between the input terminal 101 and the output terminal 104, then the data-gating circuits 220 and 320 may be sufficiently operated. As a consequence, positional relation between the data-gating circuit 220 and the data-gating circuit 320 may be replaced with each other.

Next, a description is made of a structure of the latch circuit of FIG. 2 in view of another aspect. In other words, the data-gating circuits have been described at the block level in the above case, the structure of the latch circuit is now described at a transistor level by lowering hierarchy thereof by one stage.

Each of the reversing type data-gating circuits 210 and 310 is constituted by a single P type transistor 211 or 311, whereas each of the non-reversing type data-gating circuits 220 and 320 is constituted by a single N type transistor 221 or 321.

A description is made of one concrete structure of the bistable circuit 400 at a block level by lowering hierarchy thereof by one stage. Reference numerals 401 and 402 denote inverters, while the inverters 401 and 402 are coupled to each other in a ring shape so as to constitute a bistable circuit. The bistable circuit 400 is a balloon type bistable circuit which commonly uses an input terminal of the inverter 401 and an output terminal of the inverter 402, and also, commonly uses the output terminal 104.

It should also be noted that such a terminal to which reference numeral 105 is applied corresponds to a terminal which commonly uses an output terminal of the inverter 401 and an input terminal of the inverter 402, and may function as an output terminal 105 for outputting a signal which has been inverted with respect to the signal output from the output terminal 104.

### Third Embodiment

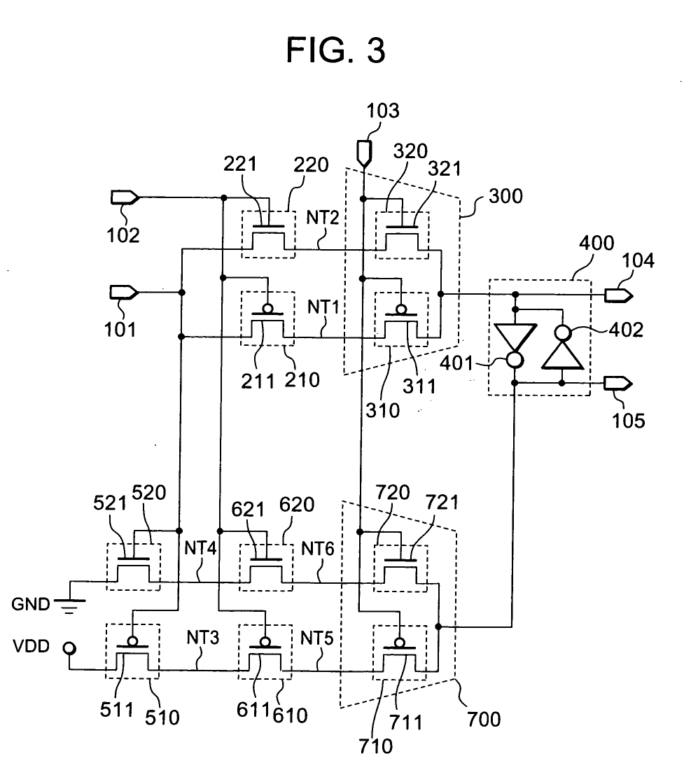

FIG. 3 is a circuit diagram showing a structure of a latch circuit according to a third embodiment of the present invention. It should be understood that the same reference numerals shown in FIGS. 1 and 2 are applied to those for denoting the same structural elements in this third embodiment.

Accordingly, a description is made of the structure of the latch circuit shown in FIG. 3 in view of one aspect. Reference numerals 510 and 520 denote a reversing type data-gating circuit and a non-reversing type data-gating circuit, respectively. In response to a signal input to the input terminal 101, the reversing type and non-reversing type data-gating circuits 510 and 520 open and/or close gates thereof. Also, reference numerals 610 and 620 denote a reversing type data-gating circuit and a non-reversing type data-gating circuit, respectively. In response to a signal input to the input terminal 102, the reversing type and non-reversing type data-gating circuits 610 and 620 open and/or close gates thereof.

Reference numeral 700 denotes a selector circuit, and is equivalent to the above-mentioned selector circuit 300. It should also be noted that, when a signal of the input terminal 103 is “L”, the selector circuit 700 outputs a signal of a terminal NT5, and, when a signal of the input terminal 103 is “H”, the selector circuit 700 outputs a signal of another terminal NT6.

The bistable circuit 400 stores thereinto an output signal from the selector circuit 700, and also, outputs this output signal to the output terminal 105.

TABLE 3

| | input | | | input | | | input | | |
|---|---|---|---|---|---|---|---|---|---|
| transition | terminal | terminal | terminal | terminal | terminal | terminal | terminal | output | |
| state | 101 | NT3 | NT4 | 102 | NT5 | NT6 | 103 | terminal 105 | |
| (A) | H | Z | L | L | Z | Z | L | L | through |
| | L | H | Z | | H | | | H | state |
| (B) | H | Z | L | H | Z | L | | latched state | |
| | L | H | Z | | | Z | | | |
| (C) | H | Z | L | L | Z | Z | H | latched state | |
| | L | H | Z | | H | | | | |
| (D) | H | Z | L | H | Z | L | | L | through |
| | L | H | Z | | | Z | | H | state |

Table 3 is a truth table for the latch circuit shown in FIG. 3. It should also be noted that, since a truth table with respect to elements of FIG. 3, which are identical to the elements shown in FIGS. 1 and 2, is identical to that of Table 1, this truth table is omitted. Also, transition states (A) to (D) represented in Table 3 are such transition states identical to the transition states (A) to (D) represented in Table 1.

In the transition state (A), under such a state that the gate of the reversing type data-gating circuit 610 is opened, the reversing type data-gating circuit 610 passes therethrough a signal appearing at the terminal NT3, or a state of this signal to the terminal NT5, and on the other hand, under such a state that the gate of the non-reversing type data-gating circuit 620 is closed, the non-reversing type data-gating circuit 620 represents “Z” with respect to the terminal NT6 irrespective of a signal appearing at the terminal NT4, or a state of this signal.

Also, in the transition state (A), the selector circuit 700 outputs a signal appearing at the terminal NT5, or a state of this signal irrespective of a signal appearing at the terminal NT6, or a state of this signal. It should be understood that the signal appearing at the terminal NT5 or the state thereof is equivalent to that of the terminal NT3.

As a consequence, when “H” is input to the input terminal 101, while the gate of the reversing type data-gating circuit 510 is closed, “Z” appears at the terminal NT3. On the other hand, when “L” is input to the input terminal 101, while the gate of the reversing type data-gating circuit 510 is opened, “H” appears at the terminal NT3. In this circuit diagram, a symbol VDD indicates a power supply voltage, and also, is equal to a voltage value equivalent to a logic value “High”.

Then, when “H” is input to the input terminal 101, the output of the selector circuit 700 represents “Z”, but, since the output of the other selector circuit 300 represents “H”, “L” appears via the inverter 401 at the terminal 105. Also, when “L” is input to the input terminal 101, the output of the selector circuit 700 represents “H”, and further, the output of the other selector circuit 300 represents “L”, and hence, “H” appears via the inverter 401 at the terminal 105. As a result, the bistable circuit 400 is stabilized to one state in a complementary manner.

Next, in the transition state (B), while the gate of the reversing type data-gating circuit 610 is closed, the reversing type data-gating circuit 610 represents “Z” with respect to the terminal NT5 irrespective of a signal appearing at the terminal NT3, or a state of this signal. On the other hand, while the gate of the non-reversing type data-gating circuit 620 is opened, the non-reversing type data-gating circuit 620 passes therethrough a signal appearing at the terminal NT4, or a state of this signal to the terminal NT6.

Also, in the transition state (B), the selector circuit 700 outputs a signal appearing at the terminal NT5, or a state of this signal irrespective of a signal appearing at the terminal NT6, or a state of this signal. In other words, since the terminal NT5 is under the state of “Z”, the bistable circuit 400 maintains such a held value right before the bistable circuit 400 is brought into the transition state (B), and also, continuously outputs the held value to the output terminal 105, and this state is the latched state of the latch circuit.

In the transition state (C), under such a state that the gate of the reversing type data-gating circuit 610 is opened, the reversing type data-gating circuit 610 passes therethrough a signal appearing at the terminal NT3, or a state of this signal to the terminal NT5, and on the other hand, under such a state that the gate of the non-reversing type data-gating circuit 620 is closed, the non-reversing type data-gating circuit 620 represents “Z” with respect to the terminal NT6 irrespective of a signal appearing at the terminal NT4, or a state of this signal.

Also, in the transition state (C), the selector circuit 700 outputs a signal appearing at the terminal NT6, or a state of this signal irrespective of a signal appearing at the terminal NT5, or a state of this signal. In other words, since the terminal NT6 is under the state of “Z”, the bistable circuit 400 maintains such a held value right before the bistable circuit 400 is brought into the transition state (C), and also, continuously outputs the held value to the output terminal 105, and this state is the latched state of the latch circuit.

Next, in the transition state (D), while the gate of the reversing type data-gating circuit 610 is closed, the reversing type data-gating circuit 610 represents “Z” with respect to the terminal NT5 irrespective of a signal appearing at the terminal NT3, or a state of this signal. On the other hand, while the gate of the non-reversing type data-gating circuit 620 is opened, the non-reversing type data-gating circuit 620 passes therethrough a signal appearing at the terminal NT4, or a state of this signal to the terminal NT6.

Also, in the transition state (D), the selector circuit 700 outputs a signal appearing at the terminal NT6, or a state of this signal irrespective of a signal appearing at the terminal NT5, or a state of this signal. It should be understood that the signal appearing at the terminal NT6 or the state thereof is equivalent to that of the terminal NT4.

As a consequence, when “L” is input to the input terminal 101, while the gate of the reversing type data-gating circuit 510 is opened, “H” appears at the terminal NT3. On the other hand, when “H” is input to the input terminal 101, while the gate of the reversing type data-gating circuit 510 is closed, “Z” appears at the terminal NT3. In this circuit diagram, a symbol GND indicates a ground potential, and also, is equal to a voltage value equivalent to a logic value “Low”.

Then, when “H” is input to the input terminal 101, the output of the selector circuit 700 represents “L”, and further, the output of the other selector circuit 300 represents “H”, and hence, “L” appears via the inverter 401 at the terminal 105. As a result, the bistable circuit 400 is stabilized to one state in a complementary manner. Also, when “L” is input to the input terminal 101, the output of the selector circuit 700 represents “Z”, but the output of the other selector circuit 300 represents “L”, and hence, “H” appears via the inverter 401 at the terminal 105.

Next, a description is made of the structure of the latch circuit of FIG. 3 in view of another aspect. In other words, the data-gating circuits have been described at the block level in the above case, the structure of the latch circuit is now described at a transistor level by lowering hierarchy thereof by one stage.

Each of the reversing type data-gating circuits 510 and 610, and a reversing type data-gating circuit 710 is constituted by a single P type transistor 511, 611, or 711, whereas each of the non-reversing type data-gating circuits 520 and 620, and a non-reversing type data-gating circuit 720 is constituted by a single N type transistor 521, 621, or 721. It should also be noted that, generally, the inverters 401 and 402 are CMOS type inverters.

Referring now to the truth table of Table 3, a description is made of specific operations of the latch circuit shown in FIG. 3 at the transistor level.

In the transition state (A), when “H” is input to the input terminal 101, in the P type transistor 211, the side of the input terminal 101 becomes a source thereof and the side of the terminal NT1 becomes a drain thereof, and in the P type transistor 311, the side of the terminal NT1 becomes a source thereof, and the side of the output terminal 104 becomes a drain thereof. As a consequence, if a voltage value having a logic value “High” input to the input terminal 101 is equal to the power supply voltage VDD, then a voltage value having a logic value “High” appearing at the output terminal 104 also becomes the power supply voltage VDD, and further, a voltage value having a logic value “Low” appearing at the output terminal 105 becomes the ground potential GND.

On the other hand, in the transition state (A), when “L” is input to the input terminal 101, in the P type transistor 211, the side of the input terminal 101 becomes the drain thereof and the side of the terminal NT1 becomes the source thereof, and in the P type transistor 311, the side of the terminal NT1 becomes the drain thereof, and the side of the output terminal 104 becomes the source thereof. As a consequence, if a voltage value having a logic value “Low” input to the input terminal 101 is equal to the ground potential GND, then a voltage value having a logic value “Low” appearing at the output terminal 104 is not lowered up to the ground potential GND, but remains at a higher potential than the ground potential GND by an absolute value of a P type transistor threshold, namely becomes “weak Low” (weak L).

Also, in the transition state (A), when “L” is input to the input terminal 101, in the P type transistor 511, the side of the power supply voltage VDD becomes a source thereof, and the side of the terminal NT3 becomes a drain thereof, in the P type transistor 611, the side of the terminal NT3 becomes a source thereof, and the side of the terminal NT5 becomes a drain thereof, and in the P type transistor 711, the side of the terminal NT5 becomes a source thereof, and the side of the output terminal 105 becomes a drain thereof. As a consequence, if a voltage value having a logic value “High” input to the input terminal 101 is equal to the power supply voltage VDD, then a voltage value having a logic value “High” appearing at the output terminal 105 also becomes the power supply voltage VDD, namely becomes “strong High” (strong H).

As a consequence, in the transition state (A), the “weak L” is output from the output terminal 104 in accordance with the circuits in the front of the selector circuit 300. However, the “strong H” appearing at the output terminal 105 in accordance with the circuits in the front of the selector circuit 700 decreases the output terminal 104 via the inverter 402 to “strong Low” (strong L), namely up to the ground potential GND.

In the transition state (D), when “H” is input to the input terminal 101, in the N type transistor 221, the side of the input terminal 101 becomes a drain thereof and the side of the terminal NT2 becomes a source thereof, and in the N type transistor 321, the side of the terminal NT2 becomes a drain thereof, and the side of the output terminal 104 becomes a source thereof. As a consequence, if a voltage value having a logic value “High” input to the input terminal 101 is equal to the power supply voltage VDD, then a voltage value having a logic value “High” appearing at the output terminal 104 is not increased up to the power supply voltage VDD, but remains at a lower potential than the power supply voltage VDD by an absolute value of an N type transistor threshold, namely becomes “weak High” (weak H).

Also, in the transition state (D), when “H” is input to the input terminal 101, in the N type transistor 521, the side of the power supply voltage VDD becomes a source thereof, and the side of the terminal NT4 becomes a drain thereof, in the N type transistor 621, the side of the terminal NT4 becomes a source thereof, and the side of the terminal NT6 becomes a drain thereof, and in the N type transistor 721, the side of the terminal NT6 becomes a source thereof, and the side of the output terminal 105 becomes a drain thereof. As a consequence, if a voltage value having a logic value “High” input to the input terminal 101 is equal to the power supply voltage VDD, then a voltage value having a logic value “Low” appearing at the output terminal 105 also becomes the ground potential GND, namely becomes “strong Low” (strong L).

As a consequence, in the transition state (D), the “weak H” is output from the output terminal 104 in accordance with the circuits in the front of the selector circuit 300. However, the “strong L” appearing at the output terminal 105 in accordance with the circuits in the front of the selector circuit 700 increases the output terminal 104 via the inverter 402 to “strong High”(strong H), namely up to the power supply voltage VDD.

On the other hand, in the transition state (D), when “L” is input to the input terminal 101, in the N type transistor 221, the side of the input terminal 101 becomes the source thereof and the side of the terminal NT2 becomes the drain thereof, and in the N type transistor 321, the side of the terminal NT2 becomes the source thereof, and the side of the output terminal 104 becomes the drain thereof. As a consequence, if a voltage value having a logic value “Low” input to the input terminal 101 is equal to the ground potential GND, then a voltage value having a logic value “Low” appearing at the output terminal 104 also becomes the ground potential GND, and further, a voltage value having a logic value “High” appearing at the output terminal 105 becomes the power supply voltage VDD.

As described above, with respect to the circuits in the front of the selector circuit 300, the circuits in the front of the selector circuit 700 functions in a complementary manner, and has an effect capable of strengthening the logic value appearing at the output terminal 104.

### Fourth Embodiment

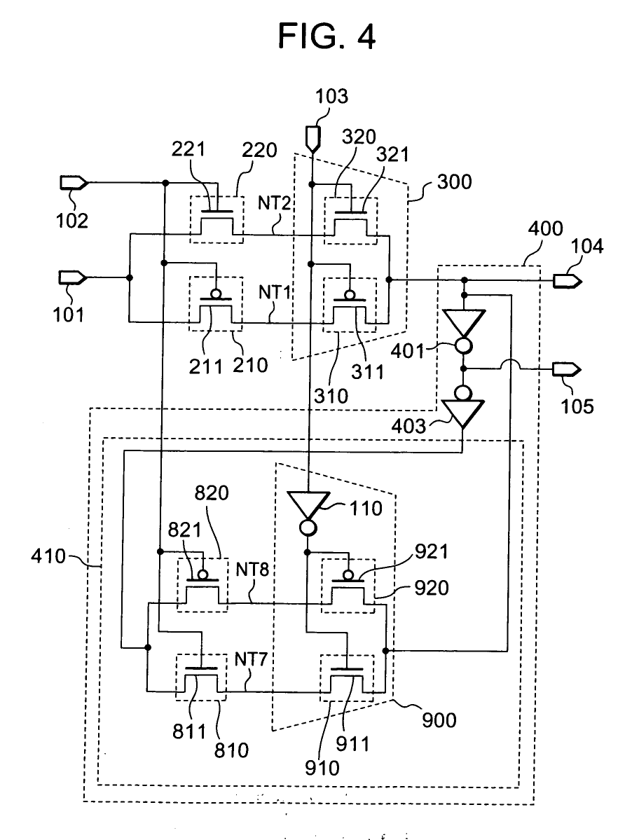

FIG. 4 is a circuit diagram showing a structure of a latch circuit according to a fourth embodiment of the present invention. It should be understood that the same reference numerals shown in FIGS. 1 and 2 are applied to those for denoting the same structural elements in this fourth embodiment.

Accordingly, a description is made of the structure of the latch circuit shown in FIG. 4 in view of one aspect. Reference numerals 810 and 820 denote a reversing type data-gating circuit and a non-reversing type data-gating circuit, respectively. In response to a signal input to the input terminal 102, the reversing type and non-reversing type data-gating circuits 810 and 820 open and/or close gates thereof. Also, reference numerals 910 and 920 denote a reversing type data-gating circuit and a non-reversing type data-gating circuit, respectively. In response to a signal input to the input terminal 103, which is inverted in an inverter 110, the reversing type and non-reversing type data-gating circuits 910 and 920 open and/or close gates thereof.

Reference numeral 900 denotes a selector circuit, and is equivalent to the above-mentioned selector circuit 300. It should also be noted that, when a signal of the input terminal 103 is “L”, the selector circuit 900 outputs a signal of a terminal NT7, and, when a signal of the input terminal 103 is “H”, the selector circuit 900 outputs a signal of another terminal NT8.

The bistable circuit 400 stores there into the output signal of the selector circuit 700, and also, outputs the stored signal to the output terminal 105. It should also be understood that the bistable circuit 400 shown in FIG. 4 is different from the above-mentioned bistable circuits 400 shown in FIGS. 2 and 3 in that the bistable circuit 400 shown in FIG. 4 inputs the output signal of the inverter 401 to an inverter 403, and further, couples the output signal of this inverter 403 via a data-gating circuit denoted by reference numeral 410 to the output terminal 104.

TABLE 4

| | input | input | | | input | | |
|---|---|---|---|---|---|---|---|
| transition | terminal | terminal | terminal | terminal | terminal | output | |
| state | 101 | 102 | NT7 | NT8 | 103 | terminal 104 | |
| (A) | H | L | Z | H | L | H | through |
| | L | | | L | | L | state |
| (B) | H | H | H | Z | | latched state | |
| | L | | L | | | | |
| (C) | H | L | Z | H | H | latched state | |
| | L | | | L | | | |
| (D) | H | H | H | Z | | H | through |
| | L | | L | | | L | state |

Table 4 is a truth table for the latch circuit shown in FIG. 4. It should also be noted that, since a truth table with respect to elements of FIG. 4, which are identical to the elements shown in FIGS. 1 and 2, is identical to that of Table 1, this truth table is omitted. Also, transition state (A) to (D) represented in Table 4 are such transition states identical to the transition states (A) to (D) represented in Table 1. As a consequence, a description is made of operations as to mainly the data-gating circuit 410 with reference to Table 4.

In the transition state (A), under such a state that the gate of the reversing type data-gating circuit 820 is opened, the reversing type data-gating circuit 820 passes therethrough an output signal of the inverter 403 to the terminal NT8, and on the other hand, under such a state that the gate of the non-reversing type data-gating circuit 810 is closed, the non-reversing type data-gating circuit 810 represents “Z” with respect to the terminal NT7.

Also, in the transition state (A), the selector circuit 900 outputs a state appearing at the terminal NT7, namely “Z” irrespective of a signal appearing at the terminal NT8, or a state of this signal.

As a consequence, the selector circuit 900 gives no effect with respect to the output terminal 104, but, at the output terminal 104, the selector circuit 300 depends upon only an output signal. In other words, under the transition state (A), namely, in the through state, the data-gating circuit 410 performs a function of avoiding that the selector circuit 900 causes a bus fight with respect to the selector circuit 300 via the output terminal 104.

Next, in the transition state (B), under such a state that the gate of the reversing type data-gating circuit 820 is closed, the reversing type data-gating circuit 820 represents “Z” with respect to the terminal NT8. On the other hand, under such a state that the gate of the non-reversing type data-gating circuit 810 is opened, the non-reversing type data-gating circuit 810 passes therethrough the output signal of the inverter 403 to the terminal NT7.

Also, in the transition state (B), the selector circuit 900 outputs a signal appearing at the terminal NT7 irrespective of a signal appearing at the terminal NT8, or a state of this signal.

As a consequence, in the transition state (B), namely in the latched state, the data-gating circuit 410 performs a function of only feeding back the output signal of the inverter 403 to the output terminal 104. As a result, the bistable circuit 400 functions as an actual bistable circuit in which the inverter 401 and the inverter 403 are coupled to each other in a ring shape in a functional mode.

In the transition state (C), under such a state that the gate of the reversing type data-gating circuit 820 is opened, the reversing type data-gating circuit 820 passes therethrough an output signal of the inverter 403 to the terminal NT8, and on the other hand, under such a state that the gate of the non-reversing type data-gating circuit 810 is closed, the non-reversing type data-gating circuit 810 represents “Z” with respect to the terminal NT7.

Also, in the transition state (C), the selector circuit 900 outputs a signal appearing at the terminal NT8 irrespective of a signal appearing at the terminal NT7, or a state of this signal.

As a consequence, in the transition state (C), namely, in the latched state, the data-gating circuit 410 performs the same function as that in the above-mentioned transition state (B).

Next, in the transition state (D), under such a state that the gate of the reversing type data-gating circuit 820 is closed, the reversing type data-gating circuit 820 represents “Z” with respect to the terminal NT8. On the other hand, under such a state that the gate of the non-reversing type data-gating circuit 810 is opened, the non-reversing type data-gating circuit 810 passes therethrough the output signal of the inverter 403 to the terminal NT7.

Also, in the transition state (D), the selector circuit 900 outputs a state appearing at the terminal NT8, namely “Z” irrespective of a signal appearing at the terminal NT7, or a state of this signal.

As a consequence, in the transition state (D), namely, in the through state, the data-gating circuit 410 performs the same function as that in the above-mentioned transition state (A).

Next, a description is made of the structure of the latch circuit of FIG. 4 in view of another aspect. In other words, the data-gating circuits have been described at the block level in the above case, the structure of the latch circuit is now described at a transistor level by lowering hierarchy thereof by one stage.

Each of the reversing type data-gating circuits 820 and 920 is constituted by a single P type transistor to which reference numeral 821 or 921 is applied, whereas each of the non-reversing type data-gating circuits 810 and 910 is constituted by a single N type transistor to which reference numeral 811 or 911 is applied. It should also be noted that, generally, the inverters 403 and 110 are CMOS type inverters.

The latch circuit shown in FIG. 4, more specifically, the bistable circuit 400 has a feature of avoiding that, in a transition period from a latched state to a through state, an output of the selector circuit 300 causes a bus fight with an output of the selector circuit 900 via the output terminal 104. It should also be noted that the bistable circuit 400 containing the data-gating circuit 410 shown in FIG. 4 may alternatively employ a structure of a new latch circuit in which this bistable circuit 400 is replaced with the bistable circuit 400 shown in FIG. 3.

### Fifth Embodiment

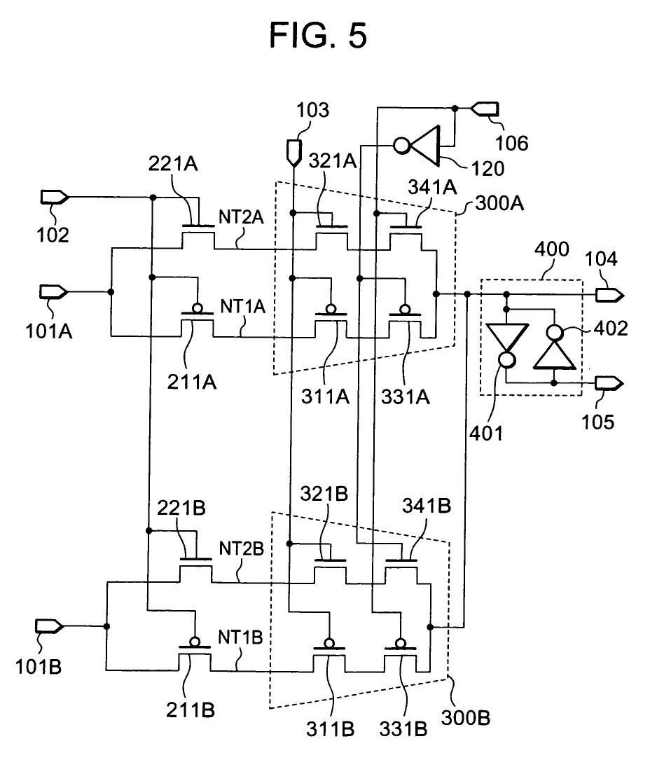

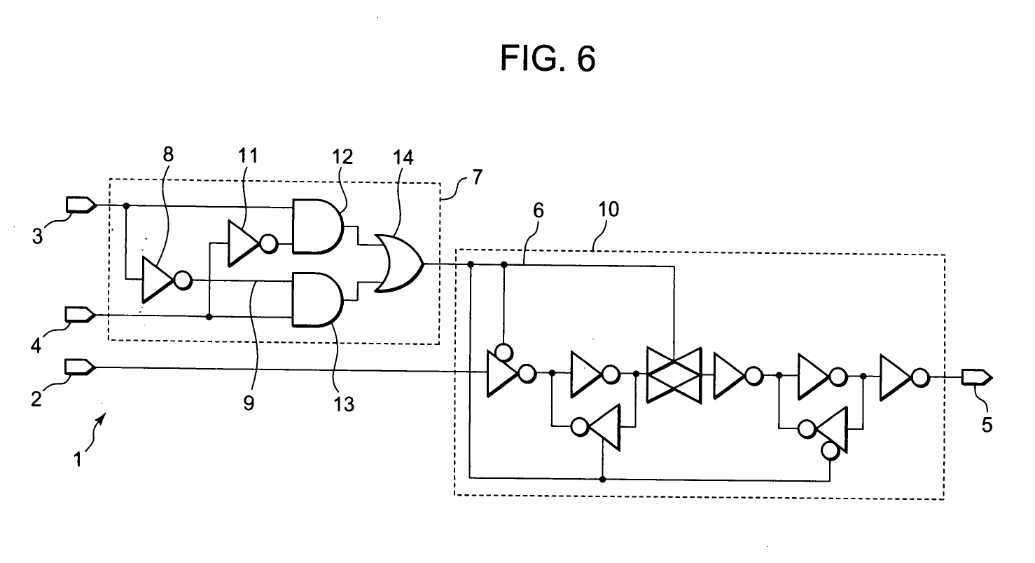

FIG. 5 is a circuit diagram showing a structure of a latch circuit according to a fifth embodiment of the present invention. It should be understood that the same reference numerals shown in FIGS. 1 and 2 are applied to those for denoting the same structural elements in this fifth embodiment. Accordingly, a description is made of the structure of the latch circuit of FIG. 5, while being compared with the latch circuit shown in FIG. 2.

Operations as to N type transistors 341A and 341B, and P type transistors 331A and 331B in response to a signal which is input to a terminal denoted by reference numeral 106 and an output signal from an inverter 120 to which the above-mentioned signal is input are now described in order to grasp behavior of the latch circuit shown in FIG. 5.

Firstly, when “H” is input to an input terminal 101A, the N type transistor 341A and the P type transistor 331A are brought into switch-ON states, whereas the N type transistor 341B and the P type transistor 331B are brought into switch-OFF states. At this stage, structural elements whose reference numerals have a symbol “B” at ends thereof give no effect to the output terminal 104, whereas only structural elements whose reference numerals have a symbol “A” at ends thereof give effects to the output terminal 104. As a consequence, if an attention is paid only to the structural elements whose reference numerals have the symbol “A” at the ends thereof, then the latch circuit shown in FIG. 5 has the function equivalent to that of the latch circuit shown in FIG. 2.

Next, when “L” is input to the input terminal 101A, the N type transistor 341A and the P type transistor 331A are brought into switch-OFF states, whereas the N type transistor 341B and the P type transistor 331B are brought into switch-ON states. At this stage, structural elements whose reference numerals have a symbol “A” at ends thereof give no effect to the output terminal 104, whereas only structural elements whose reference numerals have a symbol “B” at ends thereof give effects to the output terminal 104. As a consequence, if an attention is paid only to the structural elements whose reference numerals have the symbol “B” at the ends thereof, then the latch circuit shown in FIG. 5 has the function equivalent to that of the latch circuit shown in FIG. 2.

As described above, the latch circuit shown in FIG. 5 corresponds to the latch circuit described below. That is, one latch circuit in which the input terminal 101A is an input terminal of data, the input terminal 102 is an input terminal of a clock, and the output terminal 104 is an output terminal of the data, and another latch circuit in which an input terminal 101B is an input terminal of data, the input terminal 102 is the input terminal of the clock, and the output terminal 104 is the output terminal of the data can be selectively switched in response to a signal input to the input terminal 106.

As described above, while the latch circuit according to the present invention can avoid that the restriction of the data holding time is suppressed, the latch circuit can easily change the polarities of the clock edges, and can easily control the timing in such a case where the latch circuit is applied to the semiconductor integrated logic circuit.

The present invention is not limited only to the above-mentioned embodiments, but it is apparent that the present invention may be modified in various manners without departing from the above-mentioned gist of the present invention. For instance, two latch circuits manufactured based on the present invention may be employed, and then, a flip-flop may be realized in such a manner that those two latch circuits are defined as a master latch circuit and a slave latch circuit, and the master latch circuit is series-coupled to the slave latch circuit.

What is claimed is:

1. A latch circuit comprising:
a first terminal receiving a first signal;
a second terminal receiving a second signal;
a first data-gating circuit coupled to the first terminal and the second terminal, said first data-gating circuit non-reversely gating the second signal in response to the first signal to reveal a third signal;
a second data-gating circuit coupled to the first terminal and the second terminal, said second data-gating circuit reversely gating the second signal in response to the first signal to reveal a fourth signal;
a third terminal receiving a fifth signal;
a selector circuit coupled to the first data-gating circuit and the second data-gating circuit, said selector circuit outputting one of the third signal and the fourth signal in response to the fifth signal to latch one of the third signal and the fourth signal, respectively; and
a bistable circuit coupled to the selector circuit, said bistable circuit holding one of the third signal and the fourth signal.

2. A latch circuit comprising:
a first data-gating circuit non-reversely switching in response to a first signal;
a second data-gating circuit non-reversely switching in response to a second signal;
a first circuit including said first data-gating circuit and said second data-gating circuit coupled together in series;
a third data-gating circuit reversely switching in response to the first signal;
a fourth data-gating circuit reversely switching in response to the second signal;
a second circuit including said third data-gating circuit and said fourth data-gating circuit coupled together in series;
a first terminal receiving a third signal;
a second terminal revealing a fourth signal;
a third circuit including one circuit, the one circuit including said first circuit and said second circuit coupled together in parallel, the one circuit having one terminal being coupled to said first terminal and another terminal being coupled to said second terminal; and
a bistable circuit coupled to said second terminal, said bistable circuit holding the fourth signal.

3. The latch circuit according to claim 2,
wherein said bistable circuit comprises:
a first inverter having a first input terminal to receive a first input signal, and a first output terminal to reveal a first inverting signal for the first input signal, said first output terminal of said first inverter being coupled to said second terminal; and
a second inverter having a second input terminal to receive a second input signal, and a second output terminal to reveal a second inverting signal for the second input signal, said second input terminal of said second inverter being coupled to said second terminal, said second output terminal of said second inverter being coupled to said first input terminal of said first inverter.

4. A latch circuit comprising:
a first transistor being of a first conduction type and switching in response to a first signal;
a second transistor being of said first conduction type and switching in response to a second signal;
a first circuit including said first transistor and said second transistor coupled together in series;
a third transistor being of a second conduction type different from said first conduction type and switching in response to the first signal;
a fourth transistor being of said second conduction type and switching in response to the second signal;
a second circuit including said third transistor and said fourth transistor coupled together in series;
a first terminal receiving a third signal;
a second terminal revealing a fourth signal;
a third circuit including one circuit, the one circuit including said first circuit and said second circuit coupled together in parallel, the one circuit having one terminal being coupled to said first terminal and another terminal being coupled to said second terminal; and
a bistable circuit coupled to said second terminal, said bistable circuit holding the fourth signal.

5. The latch circuit according to claim 4,
wherein said bistable circuit comprises:
a first inverter having a first input terminal to receive a first input signal, and a first output terminal to reveal a first inverting signal for the first input signal, said first output terminal of said first inverter being coupled to said second terminal; and
a second inverter having a second input terminal to receive a second input signal, and a second output terminal to reveal a second inverting signal for the second input signal, said second input terminal of said second inverter being coupled to said second terminal, said second output terminal of said second inverter being coupled to said first input terminal of said first inverter.
